(19) United States
(12) Patent Application Publication
(10) Pub. No.: US 2022/0104344 A1
(43) Pub. Date: Mar. 31, 2022

(54) INTEGRATED PRINTED CIRCUIT BOARDS AND METHODS OF FABRICATION

(71) Applicants: Nano Dimension Technologies LTD., Nes Ziona (IL); THE IP LAW FIRM OF GUY LEVI, LLC, Wyckoff, NJ (US)

(72) Inventors: Minoru Yamada, Hong Kong (HK); Jaim Nulman, Palo Alto, CA (US); Udi Zamwell, Rehovot (IL); Michael Parthos, Ashdod (IL)

(21) Appl. No.: 17/423,860

(22) PCT Filed: Jan. 20, 2020
(86) PCT No.: PCT/US2020/014291

§ 371 Date: Jul. 17, 2021

Related U.S. Application Data
(60) Provisional application No. 62/794,105, filed on Jan. 18, 2019.

(51) Int. Cl. H05K 1/02; H05K 1/11; H05K 1/16; H05K 3/12

(52) U.S. Cl. CPC H05K 1/0284; H05K 3/125; H05K 1/16; H05K 1/11

(57) ABSTRACT

The disclosure relates to systems, methods and devices providing a modular building block towards a fabrication process for embedding a multiplicity of active and passive components in a three-dimensional structure by either automated or otherwise robotic pick and place systems, or part of the actual build of the structure, hence accelerating the miniaturization of fully functional AMEs with smaller form factor. Specifically, the disclosure is directed to the use of additive manufacturing technologies and systems, methods and compositions for fabricating multilayer AMEs having integrated active integrated circuits, RF antennas, signal indicators such as LED, and passive components such as coils, capacitor, and resistors, embedded within the AMEs.

### BACKGROUND

The disclosure is directed to systems, methods and devices providing a modular building block towards a fabrication process for embedding a multiplicity of active and passive components in a three-dimensional structure by either automated or otherwise robotic pick and place systems, or part of the actual build of the structure, hence accelerating the miniaturization of fully functional Additively Manufactured Electronic (AME) circuits, with smaller form factor. Specifically, the disclosure is directed to the use of additive manufacturing technologies and systems, methods and compositions for fabricating multilayer PCBs having integrated active circuits, RF antennas, signal indicators such as LED, and integrated passive components such as coils, capacitor, and resistors, embedded within the AMEs.

Electronic devices with small form factor are increasingly in demand in all areas of, for example: manufacture, business, consumer goods, military, aeronautics, internet of things, and others. Products having these smaller form factors rely on compact AMEs with tightly spaced digital and analog circuits placed in close proximity. Increased device complexity, can lead to a substantial increase in the AME's circuits' layer count. The increase in layer count typically results from increased functionality requirement combined with the demand for smaller footprint and a more compact form factor, for example in mobile communication devices. However, the limitation on miniaturization arises from the methods to fabricate and assemble these devices in the manufactured electronics. Furthermore. The methods used today require for passive devices such as capacitors, resistors, and inductive coils to take precious real state in the manufactured electronics, which further limits the opportunity for size reduction and increases both the complexity and cost of manufacturing.

There is an increasing demand for these (small) devices to perform a substantially larger and more complex number of electronic functions. Moreover, because active devices that are shrinking in size and are packaged in advanced packaging (e.g., ball-grid arrays (BGAs), micro-BGAs, quad-flat packs (QFP), and chip scale packaging (CSP)), add to the complexity and issues associated with small form factor AMEs, OEMs demand an even greater robustness, higher quality, better fault tolerance, increased reliability, lower ‘parasitic’ or ‘bleeding’ interconnects, and better yields associated with these (small form factor) designs. All these requirements need to minimize the length of the connectivity between these active devices, hence requiring vertical integration as well as close proximity.

The development of complex electronics requires research, development and engineering of a substantial number of prototypes of Additively Manufactured Electronic (AME) circuits (AMEs), each requiring quality assurance tests, fault tolerance tests, efficiency tests and more, prior to being transferred to mass production. Each AME circuit further requires planning processes, fabrication, purchasing and assembly, with the fabrication process being typically, the most substantial bottleneck for the process in terms of time and costs. Not insubstantial as well, is the risk of exposing trade secrets. These risks are currently inevitable, since the costs associated with faulty design and malfunctions during the mass production stage are order(s) of magnitude higher, both in terms of costs, as well as in damage to reputation.

The present disclosure is directed toward overcoming one or more of the above-identified shortcomings by the use of additive manufacturing technologies and systems.

### SUMMARY

Disclosed, in various embodiments, are systems, methods and compositions configured to provide a single, integrated AME circuits or modular building blocks towards a fabrication process for fully integrating passive components and providing receptacles, or wells for either vertically or horizontally embedding multiplicity of single or a plurality of active and passive discrete components with automated or otherwise robotic pick and place. Specifically, the disclosure is directed to systems and methods for fabricating multilayer AMEs having integrated passive and active components embedded within the AME circuits either horizontally, vertically integrated, or a combination of both.

In an embodiment provided herein is a method for reducing the form factor of an Additively Manufactured Electronic (AME) circuits comprising a plurality of passive and active components using additive manufacturing technologies such as inkjet printer comprising: providing an ink jet printing system having: a first print head adapted to dispense a dielectric ink; a second print head adapted to dispense a conductive ink; a conveyor, operably coupled to the first and second print heads, configured to convey a substrate to each print heads; and a computer aided manufacturing (“CAM”) module in communication with the first print head, the second print heads, and the conveyor, the CAM module comprising: at least one processor; a non-volatile memory; and a set of executable instructions stored on the non-volatile memory, configured, when executed to cause the at least one processor to: receive a 3D visualization file representing an infrastructure element; using the 3D visualization file, generate a library comprising a plurality of layer files, each layer file representing a substantially 2D layer for printing of the AME circuit comprising the plurality of embedded passive and active components; using the library, generate a conductive ink pattern comprising the conductive portion of each of the layer files for printing a conductive portion of the AME circuit using the library, generate an ink pattern corresponding to the dielectric inkjet ink portion of each of the layer files for printing a dielectric portion of the PCB.

It is noted, that the library comprises computer aided design (CAD)-generated layout of traces and dielectric insulating material, and the metafile required for their retrieval, including for example, labels, printing chronological order and other information needed for using in the additive manufacturing systems used.

The CAM module is configured to control each of the first and the second print heads; providing the dielectric inkjet ink composition, and the conductive inkjet ink composition; using the CAM module, obtaining the first layer file; using the first print head, forming the pattern corresponding to the dielectric inkjet ink; curing the pattern corresponding to the at least one of the insulating and the dielectric inkjet ink; using the second print head, forming the pattern corresponding to the conductive inkjet ink; sintering the pattern corresponding to the conductive inkjet ink; and optionally coupling at least one active component to the printed first layer, wherein the conductive inkjet ink and the dielectric inkjet ink are adapted to form passive components embedded within the first layer. It is noted, that sintering and curing are separate processes that can take place at any convenient order as is the printing of the conductive and dielectric patterns. Where the conductive layer provides for signal transfer between the embedded components and/or the outside components.

In either exemplary implementation, the same method can be applied with a system having a plurality of inks and printing them in parallel or is serial order. Furthermore the skilled artisan would recognize that other methods of additive manufacturing can be used to achieve the same result. As used herein, the term “additive manufacturing” includes any system that may be used to fabricate the structures described herein by an additive manufacturing process, such as the additive manufacturing processes described. Furthermore, it stands to reason that a multiplicity of printer heads, or other dispensing sources, can be used for adding either materials or increasing process throughput via duplication of dispensing sources for the same material.

In another embodiment, provided herein is at least one of: a printed circuit board (PCB), a flexible printed circuit (FPC), and a high-density interconnect printed circuit board (HDIPCB), each comprising a plurality of capacitors embedded entirely within a dielectric matrix. In the context of the disclosure, “dielectric matrix” refers to a physical medium that surrounds and holds components. A matrix may be a three-dimensional material block which has recesses or holes which are basically entirely filled with the active or passive components, consequently holding the active or passive components in place. A matrix may thus denote a principal phase of a material in which another constituent is embedded. In an exmple, the volume of the matrix material may be larger than the volume of the active or passive component. A matrix may be a dielectric ink chamber where active or passive components were placed and printed over while in place thus embedding these active or passive components entirely within the DI material using additive manufacturing as disclosed and claimed herein.

In yet another embodiment, provided herein is at least one of: a printed circuit board (PCB), a flexible printed circuit (FPC), and a high-density interconnect printed circuit board (HDIPCB), each comprising a plurality of concentric nested contact pads, and an active component receptacle, each contact pad sized and configured to operably couple to a chip package.

In an embodiment, the capacitors provided herein, and/or the chip package are encapsulated in at least one of a floating and grounded shielding capsule adapted to shield the at least one capacitor from at least one of a UV, infra-red, electromagnetic or radio frequency irradiation.

In an embodiment, other passive components such as inductors and resistors provided herein, are encapsulated in at least one of a floating and grounded shielding capsule adapted to shield the at least one inductor or resistor from at least one of a UV, infra red, electromagnetic or radio frequency irradiation.

These and other features of the systems, methods and compositions for the direct and continuous fabrication of printed circuit boards (AMEs) with integrated active and passive components, will become apparent from the following detailed description when read in conjunction with the figures and examples, which are exemplary, not limiting.

### BRIEF DESCRIPTION OF THE FIGURES

For a better understanding of the direct additive manufacturing for printing of AMEs with either embedded or vertically integrated passive components and vertically and or horizontal integrated active components, their fabrication methods and compositions, with regard to the embodiments thereof, reference is made to the accompanying examples and figures, in which:

FIG. 1, is a Z-X cross section of an AME circuit schematic illustrating a first embodiment of horizontally integrated capacitors' configuration fabricated using the disclosed methods;

FIG. 2, is a X-Y plan view of the PCB schematic illustrated in FIG. 1;

FIG. 3, is a Z-X cross section of an AME circuit schematic illustrating a second embodiment of horizontally integrated capacitors' configuration fabricated using the disclosed methods;

FIG. 4A is a Z-X cross section of an AME circuit schematic illustrating a first embodiment of vertically integrated capacitors' configuration fabricated using the disclosed methods, with 2-port interdigitated capacitor electrodes in order to achieve a desired capacitance value, with FIG. 4B being Z-X cross section of an AME circuit schematic illustrating a second embodiment of vertically integrated capacitors' configuration, showing individual capacitors' electrode pairs, FIG. 4C illustrating X-Y being a plan of an AME circuit schematic illustrating a third embodiment of vertically integrated capacitors' showing circular concentric electrode configuration, with its X-Z cross section illustrated in FIG. 4D.

FIG. 5A, is a Z-X cross section of a vertically integrated PCB schematic illustrating graduated, nested wells for vertically stacked and embedded chip packages, with FIG. 5B illustrating FIG. 5A further comprising SMT type pads on the structure manufactured using the disclosed methodology for further mounting of the structure on a standard PCB, while FIG. 5C, illustrating FIG. 5A further comprising a heat sink or an opening that allows for convection flow of cooling air or forced cooling air by the integration of a properly sized fan, and FIG. 5D illustrating a vertically integrated PCB schematic illustrating graduated, nested wells vertically integrated and embedded chip packages, a battery receptacle and an induction coil/RF antenna embedded, with an isometric view of a similar arrangement illustrated in FIG. 5E whereby the vertically integrated ICs are powered by an a battery placed in a specifically fabricated well, including the necessary contacts for the battery, and RF antenna or inductive coil around the vertically integrated chips.

FIG. 6A illustrates Multi-layered PCB fabricated by additive manufacturing where part of it represents standard PCB thicknesses/layers and with one sided vertical integration of components described in FIG. 5A, FIG. 5C, and FIG. 5D, with FIG. 6B, illustrating a double sided, vertically integrated PCB, in these cases the active and passive devices present in the vertical component are directly interconnected by the electrical traces to other components and elements of the standard portion of the PCB.

FIG. 7A illustrating an AME circuit with passive grounded monodirectional DC-DC converter, with a bidirectional DC-DC converter illustrated in FIG. 7B, for simplicity of the illustration, the coils around the vertical elements of the transformer are not shown, but it is obvious to any one skilled in the art that their presence is essential;

FIG. 8, illustrating simple dual plate horizontal capacitors (left), as well as interdigitated capacitor plate arrangement (right), both encased in a UV/RF/Electromagnetic shielding fabricated using additive manufacturing;

FIG. 9A, is a graph (bottom) showing the dependence of relative permittivity (εᵣ) on horizontal capacitors' having fixed dielectric (DI) thickness between electrodes as a function of the distance of the top electrode from the top surface of the PCB (i.e DI thickness) in a Z-X cross section of an AME circuit (coupon) schematic (top), with FIG. 9B, of a graph (bottom) showing the dependence of relative permittivity (εᵣ) on horizontal capacitors' having varying dielectric (DI) thickness between electrodes as a function of the thickness between electrodes in a Z-X cross section of an AME circuit (coupon) schematic; and

FIGS. 10-15 showing the dependence of relative permittivity (εᵣ) on various processing variables (graph titles).

### DETAILED DESCRIPTION

Provided herein are embodiments, examples and implementations of systems, methods and compositions configured to provide modular building blocks towards an additive fabrication process for fully integrating passive components and providing receptacles, or wells for embedding vertically and/or horizontally placed active and passive components manually or with automated or otherwise robotic pick and place systems. Specifically, provided herein are embodiments, examples and implementations of systems, methods and compositions for fabricating multilayer AME circuits having integrally fabricated-passive and active components embedded within the PCB.

Technologies for the embedding of active and passive components into multilayered AMEs have become a necessity for the development of complex electronics. Different embedding technologies have been developed due to different requirements with respect to electrical performance, chip dimensions, and interconnection. Moreover, Package-on-Package technology (PoP) has also been expanding (e.g., from mobile devices to PCs), even in devices where reduced footprint less of a requirement, if only to increase functionality, for example FOVEROS™ by Intel.

Traditional printed circuit boards (PCB)s and other AMEs, typically have a thickness of between about 0.7 to about 1.6 mm with active (in other words, electronic components that are capable of controlling current), and passive (in other words, electronic components that are incapable of controlling current by means of another electrical signal) components, mounted on either one, or both sides of the PCB. This limits the packaging density and the capabilities to a maximum of two layers of active components one in each opposite side of the PCB and similarly for passive components.

Provided herein, is a novel structure and fabrication method for AMEs, which is based on additive manufacturing resulting inter-alia, in:
Multi stacking—of at least two active components such as ICs;
Multi stacking—of at least one passive component in conjunction with multi-layered stack of active ICs, such as capacitors, inductors, and resistors;
Built-in (integrated) passive components such as inductors, coils, resistors and capacitors;
Integrated DC-DC and AC-DC power converters;
Integrated signal indicators such as LEDs and solid state lasers,
Combination of multi-layer, stepped (see e.g., FIGS. 5A-5C) PCB dielectric structures, configured to accommodate the varying degrees of active and passive components;
Integrated cooling structures, whereby cooling can be done by, for example, means of air, coolants, and metallic heat dissipation structures (e.g., heat sinks), and specifically routed coolant passages enabled by the use of sacrificial additive manufacturing material that is removed upon completion of the baseline structure manufacturing process;
Integrated power sources housing/receptacles/wells/slots and the like, such as for a battery, solar cell, etc.;
(Compactly) Packaged active and passive devices to be mounted on much larger AMEs as unique modular building blocks to be incorporated with other AMEs.
Shorter interconnect distances among active and passive components.
Shorter interconnect distances among the integrated section and other sections of the PCB

In an exemplary implementation, provided herein, is a novel method of packaging active and passive components on a small form factor (in other words, the body outline and footprint) with built-in contact pads at the outer layers (e.g., bottom) of the structure, such as the ones used in surface mounted technology (SMT), as well as ball-grid array (BGA). These contact pads can be soldered into a much larger AME circuits, or otherwise operably couple to a similar AME circuits, in effect forming modular AME circuits' blocks that can be assembled with optimal packaging density. In addition, cooling capabilities—if necessary, can be provided by integrally fabricating either heat conductive metal traces/pads which can be used also as electrical ground planes, or cavities and/or hollow layers through which a coolant can be configured to flow, with either air, other gases, or liquids. All of these coolants can be actuated by means of integrated active coolant flow devices, for example, forced air through a micro-fan, piezo-fans, ‘synthetic’ jet cooling and ‘nanolightning’ (‘micro-scale ion-driven airflow’ using very high electric fields created by nanotubes that can be printed as vias (using the systems provided), or blower, liquid cooling (direct and indirect) using e.g., electromagnetic pumps and sensors, and thermoelectric (PELTIER) coolers (TECs), and their combination.

Passive cooling can also be affected using the systems and methods provided. In the simplest configuration; coolant path with air, additive manufacturing enables the creation of vertical paths in the structures where electrical connections do not take place, while the use of support material during the additive manufacturing enables the creation of vertical and horizontal paths for active cooling with air and/or other gases, and/or liquids.

Here, the systems, methods and compositions described can be used to form/fabricate the AME circuits including built-in passive and embedded active components, using a combination of print heads with conductive and dielectric ink compositions in a continuous additive manufacturing process using the inkjet printing device, in a single pass, or using several passes. Using the systems, methods and compositions described herein, a thermoset resin material can be used to form the insulating and/or dielectric portion of the printed circuit boards (see e.g., 101 FIG. 1). This printed dielectric inkjet ink (DI) material is printed in optimized shape including accurate compartments (or voids) shaped to accommodate, when necessary, embedded active components.

While reference is made to inkjet inks, other additive manufacturing methods are also contemplated in the implementation of the disclosed methods. In one exemplary embodiment, the fully integrating passive components and providing receptacles, or wells for embedding multiplicity of single or a plurality of active and passive discrete components can likewise be fabricated by a selective laser sintering (SLS) process, although any other suitable additive manufacturing process (also known as rapid prototyping, rapid manufacturing, and 3D printing) may be used, such as direct metal laser sintering (DMLS), electron beam melting (EBM), selective heat sintering (SHS), or stereolithography (SLA). The fully integrated passive components and receptacles, or wells for embedding multiplicity of single or a plurality of active and passive discrete components may be fabricated from any suitable additive manufacturing material, such as metal powder(s) (e.g., cobalt chrome, steels, aluminum, titanium and/or nickel alloys), gas atomized metal powder(s), thermoplastic powder(s) (e.g., polylactic acid (PLA), acrylonitrile butadiene styrene (ABS), and/or high-density polyethylene (HDPE)), photopolymer resin(s) (e.g., UV-curable photopolymers such as, for example PMMA), thermoset resin(s), thermoplastic resin(s), or any other suitable material that enables the functionality as described herein.

The systems used can typically comprise several sub-systems and modules. These can be, for example: a mechanical sub-system to control the movement of the print heads, the substrate (or chuck) its heating and conveyor motions; the ink composition injection systems; the curing/sintering sub-systems (configured to operate separately on each of DI/CI inks respectively); a computerized sub-system with a processor or CPU that is configured to control the process and generates the appropriate printing instructions, a component placement system such as automated robotic arm, a machine vision system, and a command and control system to control the 3D printing.

Accordingly and in an exemplary implementation, provided herein is a method for reducing the form factor of a printed circuit board (PCB) AME circuits comprising a plurality of passive and active components using inkjet printer, the method comprising: providing an ink jet printing system having: a first print head adapted to dispense a dielectric ink; a second print head adapted to dispense a conductive ink; a conveyor, operably coupled to the first and second print heads, configured to convey a substrate to each print heads; and a computer aided manufacturing (“CAM”) module in communication with the first print head, the second print heads, and the conveyor, the CAM module comprising: at least one processor; a non-volatile memory; and a set of executable instructions stored on the non-volatile memory, configured, when executed to cause the at least one processor to: receive a 3D visualization file representing the infrastructure element; using the 3D visualization file, generate a library comprising a plurality of layer files, each layer file representing a substantially 2D layer for printing of the AME circuit comprising the plurality of embedded passive and active components; using the library, generate a conductive ink pattern comprising the conductive portion of each of the layer files for printing a conductive portion of the AME circuit using the library, generate an ink pattern corresponding to the dielectric inkjet ink portion of each of the layer files for printing a dielectric portion of the AME circuit, wherein the CAM module is configured to control each of the first and the second print heads; providing the dielectric inkjet ink composition, and the conductive inkjet ink composition; using the CAM module, obtaining the first layer file; using the first print head, forming the pattern corresponding to the dielectric inkjet ink; curing the pattern corresponding to the at least one of the insulating and the dielectric inkjet ink; using the second print head, forming the pattern corresponding to the conductive inkjet ink; sintering the pattern corresponding to the conductive inkjet ink; and optionally coupling at least one active component to the printed first layer, wherein the conductive inkjet ink and the dielectric inkjet ink are adapted to form passive components embedded within the first layer, wherein the steps of curing and sintering are performed separately from each other (in other words, unless indicated specifically, curing is not used for sintering, nor sintering is used for curing, although the order is immaterial and can happen in sequence or simultaneously).

The use of the term “module” does not imply that the components or functionality described or claimed as part of the module are all configured in a (single) common package. Indeed, any or all of the various components of a module, whether control logic or other components, can be combined in a single package or separately maintained and can further be distributed in multiple groupings or packages or across multiple (remote) locations and devices. Furthermore, in certain embodiments, the term “module” refers to a monolithic or distributed hardware unit.

In an exemplary implementation, the term “dispenser” is used to designate the device from which the inkjet ink drops are dispensed. The dispenser can be, for example an apparatus for dispensing small quantities of liquid including micro-valves, piezoelectric dispensers, continuous-jet print-heads, boiling (bubble-jet) dispensers, and others affecting the temperature and properties of the fluid flowing through the dispenser.

The set of executable instructions are further configured, when executed to cause the processor to generate a library of a plurality of subsequent layers' files from the 3D visualization file. Each subsequent file represents a substantially two dimensional (2D) subsequent layer for printing a subsequent portion of the AME circuit comprising the plurality of embedded passive and active components, wherein each subsequent layer file is indexed by printing order. Furthermore, the set of executable instructions can be configured to parse out the conductive and dielectric portions of each 2D layer, and create a unique pattern per each layer from the first and on, that will instruct the proper print head to print that portion of the 2D layer.

Accordingly and in an exemplary implementation, the methods implemented using the systems and compositions provided for fabricating AME circuits comprising built-in passive, and embedded passive and/or active components, further comprise, prior to the step of coupling the at least one active component (for example by automatically placing ICs and soldering those into the slow or well) or similarly at least one passive component, if carried out: using the CAM module, accessing the library; obtaining a generated file representing 2D subsequent layer of the AME circuit; and repeating the steps for, and forming the subsequent layer. The skilled artisan would readily recognize that each 2D file is a layer, or slice of a predetermined thickness corresponding to the print head parameters, which is derived from the 3D visualization file that was generated and rendered automatically, to include the pattern of conductive and dielectric patterns for that particular layer, including, for example, voids not to be printed with any ink, thus when assembled vertically, can form the chambers sized and configured to receive the embedded active and/or passive components.

The term “chip” refers to a packaged, singulated, IC device. The term “chip package” may particularly denote a housing that chips come in for plugging into (socket mount) or soldering (surface mount) onto a circuit board such as a printed circuit board (PCB), thus creating a mounting for a chip. In electronics, the term chip package or chip carrier may denote the material added around a component or integrated circuit to allow it to be handled without damage and incorporated into a circuit. In certain implementations, the embedded active and passive devices may be incorporated as either a chip, or as a chip package and should be interchangeable. Furthermore, unless specifically indicated, a chip package includes a singulated chip and not a plurality of chips on a single chip package.

The CAM module can therefore comprise: a 2D-file-library storing the files converted from the 3D visualization files of the AME circuit including built-in passive and embedded active components. The term “library, as used herein, refers to the collection of 2D layer files derived from the 3D visualization file, containing the information necessary to print each conductive and dielectric pattern, in each layer at the proper sequence, which is accessible and used by the data collection application, which can be executed by the computer-readable media, all stored and implementable on the CAM. The CAM further comprises at least one processor in communication with the library; a memory device storing a set of operational instructions for execution by the at least one processor; a micromechanical inkjet print head or heads in communication with the at least one processor and with the library; and a print head (or, heads') interface circuit in communication with the 2D file library, the memory and the micromechanical inkjet print head or heads, the 2D file library configured to provide printer operation parameters specific to a functional layer. In the context of the disclosure, a functional layer refers to the layer as it defined in the 2D file library, having the dielectric and/or conductive ink patterns for printing the layer sequence order and the thickness of each dielectric and conductive patterns to be printed.

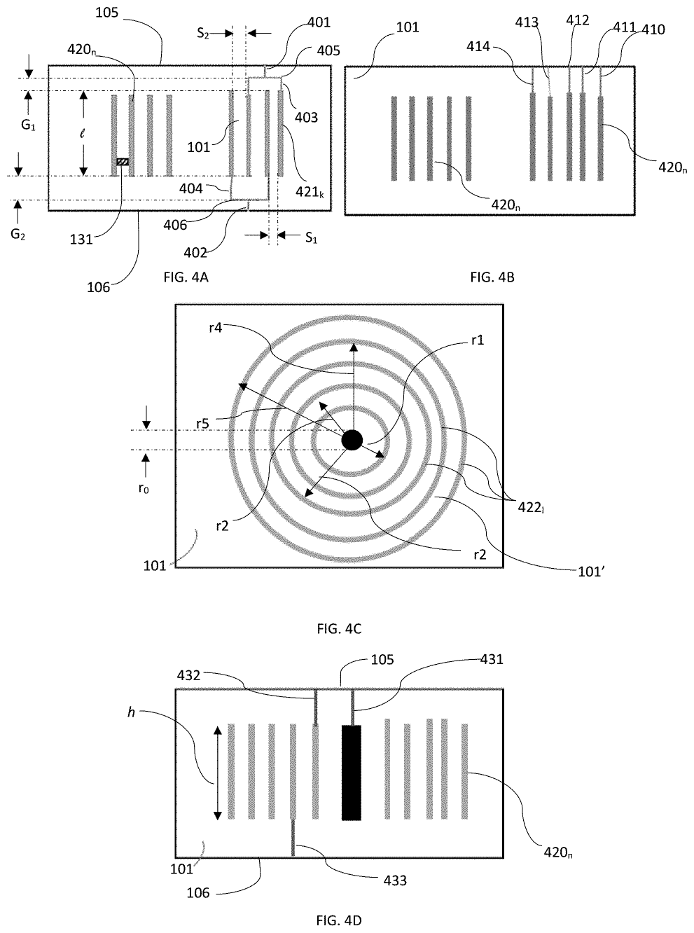

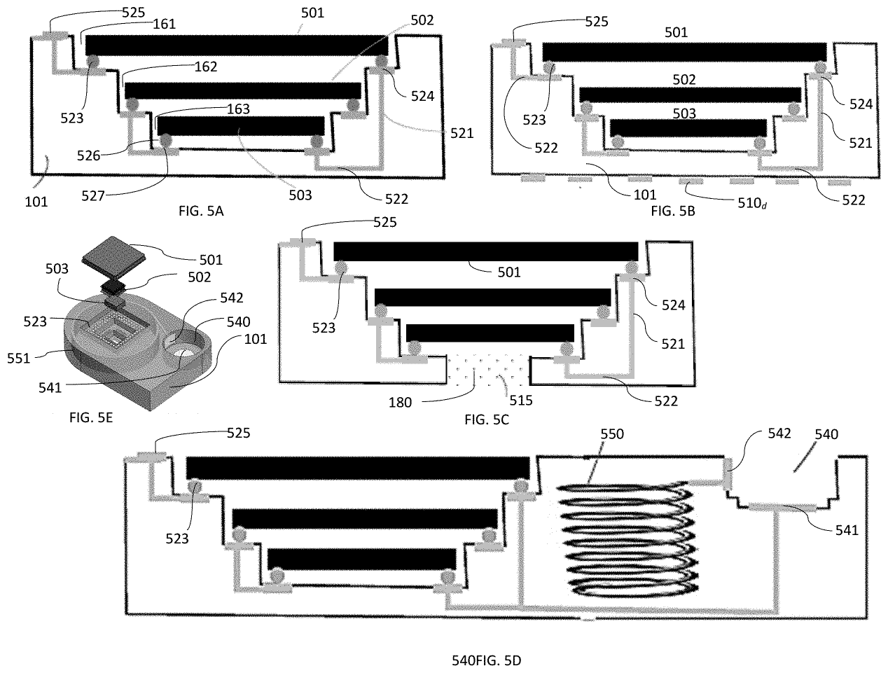

The passive components built-in to the multi-layered AME circuits fabricated using the methods provided in the systems disclosed, can be, for example, at least one of an inductor, a capacitor (See e.g., 110ᵢ, 111ⱼ FIG. 1), a resistor (see e.g., 131 FIG. 4A), a coil, an antenna (for example, trace antennae, see e.g., FIG. 5C, 550), a cooling pad, a heat-pipe, a condenser, a wick, a cooling platform, a vapor chamber, a socket, and a contact pad (see e.g., 524 FIG. 5A). In an exemplary implementation, heat pipes (or plated/hollow vias) 102p (FIG. 1), 521 (FIG. 5B), can be plated pipes that are configured to operate as sintered (heat) wicks or, printed directly as grooved internal cross section, adapted to operate as grooved wicks.

In an exemplary implementation, the AME circuit is a multi-layered AME circuit, defining a hollow (in other words, empty) intermediate layer and wherein at least one of the cooling pad, the heat pipe, and the wick terminates at the hollow intermediate layer. For example, heat pipes (or filled/plated vias 521) can terminate at a hollow intermediate layer (not shown), which can be in fluid (gas, air) communication with a ventilation source, for example a piezo fan that will create airflow through the hollow layer. Additionally, or alternatively, the heat pipes can terminate at the basal layer of the AME circuit (interchangeable with flexible printed circuits (FPC) and high-density interconnect printed circuits (HDIPC)). The heat pipes (or filled/plated vias 521) can be direct extensions to cooling metal block printed using the systems disclosed, rather than being bonded (grazed) with a solder paste, thus creating a better connection and more efficient heat wicking. In addition, in other examples, two-phase heat pipe can be directly printed, in which heat can be transferred from the cooled component through thermodynamic phase change of a liquid to vapor (latent heat of evaporation) and back to liquid, whereby the liquid is passively passed from the evaporator to a condenser via capillary action, whereby the capillaries are integrally fabricated during the various layer assembly.

Furthermore, the chip or chip package (containing that chip) used in conjunction with the systems, methods and compositions described herein can be Quad Flat Pack (QFP) package, a Thin Small Outline Package (TSOP), a Small Outline Integrated Circuit (SOIC) package, a Small Outline J-Lead (SOJ) package, a Plastic Leaded Chip Carrier (PLCC) package, a Wafer Level Chip Scale Package (WLCSP), a Mold Array Process-Ball Grid Array (MAPBGA) package, a Ball-Grid Array (BGA), a Quad Flat No-Lead (QFN) package, a Land Grid Array (LGA) package, a passive component, or a combination comprising two or more of the foregoing.

In certain embodiments, the systems provided herein further comprise a robotic arm in communication with the CAM module and under the control of the CAM module, configured to place each of the plurality of active components in its designated location, which can be fabricated by the system.

In certain embodiments, semiconductor die or device, (e.g., a dynamic random access memory (DRAM) or a microprocessor), can be directly mounted on the platforms, wells, slots or otherwise a designated embedding sites in the AME circuit, which can have a plurality of bond pads (see e.g., 510d, FIG. 5B) in single column or multiple columns on an active surface of the active component without the need for the traditional die package. Circuit traces located on or within the PCB incorporating the active component serve to maintain electric communication between bond pads and 510d respective electrically conductive, connective elements such as solder balls 523 (See e.g., FIG. 5A). The electrically-conductive elements typically comprise solder balls 523 in electrical communication with and attached to contact pad (e.g., 524), or can merely be solder ball 526 placed directly upon, or in electrical communication with, the termination point 527 of a selected circuit trace.

The conductive elements or balls can, for example, be arranged in a grid array pattern wherein the conductive elements or solder balls are of a preselected size or sizes and are spaced apart from each other at one or more preselected distances, or pitches. Hence, the term “fine ball grid array” (FBGA) merely refers to a particular ball grid array pattern having what are considered to be relatively small conductive elements or solder balls being spaced at very small distances from each other resulting in dimensionally small spacing or pitch. As generally used herein, the term “ball grid array” (BGA) encompasses fine ball grid arrays (FBGA) as well as ball grid arrays. Accordingly and in an exemplary implementation, the pattern representative of the conductive ink printed using the methods described herein, is configured to fabricate interconnect (in other words, solder) balls. In certain exemplary implementations, the system can be configured to form small dimple sized and configured to receive a ball and form the BGA.

Alternatively, or additionally, the additive manufacturing systems used in the methods and compositions for fabricating printed circuit boards including built-in passive and embedded active components, can further comprise a third print head (a fourth or any additional number of additional functional printing heads) or source materials, adapted to dispense a second conductive inkjet ink (in other words, an additional type of conductive inkjet ink), the method further comprising: providing the second conductive ink composition; using the second conductive ink print head, forming a predetermined pattern corresponding to the second conductive inkjet ink, the pattern being a 2D presentation of a connecting terminal, a bond to a lead, an interconnect ball, or a combination thereof.

In an exemplary implementation, the first conductive inkjet ink can contain silver, while the second inkjet ink can contain copper, thus allowing printing of integral, built-in capacitors having silver electrodes, with copper connection terminals. Similarly, the additive manufacturing systems can further comprise an additional print head, adapted to dispense another dielectric inkjet ink, the method further comprising: providing the additional dielectric inkjet ink (DI) composition; using the additional print head, forming a predetermined pattern corresponding to the additional dielectric inkjet ink, the pattern being a 2D presentation of, for example; a ceramic capacitor layers, a RF antenna coil spacers, and the like. For example, the second DI can be ceramic ink composition comprising organically modified, silicate-based ceramic (ORMODS) co-monomers, which can have a ceramic constituent, configured to polymerize via sol-gel mechanism, conjugated to vinyl/acrylate/methacrylate constituents configured to polymerize via free radical polymerization and form a bi-continuous phase of ceramic-polymer interpenetrated networks. Accordingly and in an exemplary implementation, the systems and methods described herein can be used to form either stand-alone (discrete), or integral, built-in multi-layer ceramic capacitor (MLCC). Likewise, using the ceramic DI, the systems and methods provided herein can be adapted to fabricate at least one of a discrete or an integral, built-in ceramic antennae, for example, monopole antenna, inverted-F antenna, or planar inverted-F antenna, thus providing the advantage of ceramic antenna (lower detuning risks, lower environmental sensitivity e.g.) with PCB trace antenna advantages (lower form factor, manufacturing costs, e.g.,). Although indicated as additional print heads, it is contemplated that two or more inkjet printers can be combined to form a single system.

The term “forming” (and its variants “formed”, etc.) refers in an exemplary implementation to pumping, injecting, pouring, releasing, displacing, spotting, circulating, or otherwise placing a fluid or material (e.g., the conducting ink) in contact with another material (e.g., the substrate, the resin or another layer) using any suitable manner known in the art. Likewise, the term “embedded” refers to the chip and/or chip package being coupled firmly coupled within a surrounding structure, or enclosed snugly or firmly within a material or structure.

Curing the insulating and/or dielectric layer or pattern deposited by the appropriate print head as described herein, can be achieved by, for example, heating, photopolymerizing, drying, depositing plasma, annealing, facilitating redox reaction, irradiation by ultraviolet beam or a combination comprising one or more of the foregoing. Curing does not need to be carried out with a single process and can involve several processes either simultaneously or sequentially, (e.g., drying and heating and depositing crosslinking agent with an additional print head)

Furthermore, and in another embodiment, crosslinking refers to joining moieties together by covalent bonding using a crosslinking agent, i.e., forming a linking group, or by the radical polymerization of monomers such as, but not limited to methacrylates, methacrylamides, acrylates, or acrylamides. In some embodiment, the linking groups are grown to the end of the polymer arms.

Therefore, in an exemplary implementation, the vinyl constituents are monomers comonomers, and/or oligomers selected from the group comprising a multi-functional acrylate, their carbonate copolymers, their urethane copolymers, or a composition of monomers and/or oligomers comprising the foregoing. Thus, the multifunctional acrylate is 1,2-ethanediol diacrylate, 1,3-propanediol diacrylate, 1,4-butanediol diacrylate, 1,6-hexanediol diacrylate, dipropylene glycol diacrylate, neopentyl glycol diacrylate, ethoxylated neopentyl glycol diacrylate, propoxylated neopentyl glycol diacrylate, tripropylene glycol diacrylate, bisphenol-A-diglycidyl ether diacrylate, hydroxypivalic acid neopentanediol diacrylate, ethoxylated bisphenol-A-diglycidyl ether diacrylate, polyethylene glycol diacrylate, trimethylolpropane triacrylate, ethoxylated trimethylolpropane triacrylate, propoxylated trimethylolpropane triacrylate, propoxylated glycerol triacrylate, tris(2-acryloyloxyethyl)isocyanurate, pentaerythritol triacrylate, ethoxylated pentaerythritol triacrylate, pentaerythritol tetraacrylate, ethoxylated pentaerythritol tetraacrylate, ditrimethylolpropane tetraacrylate, dipentaerythritol pentaacrylate and dipentaerythritol hexaacrylate or a multifunctional acrylate composition comprising one or more of the foregoing

In an exemplary implementation, the term “copolymer” means a polymer derived from two or more monomers (including terpolymers, tetrapolymers, etc.), and the term “polymer” refers to any carbon-containing compound having repeat units from one or more different monomers.

Other functional heads may be located before, between or after the inkjet ink print heads used in the systems for implementing the methods described herein. These may include a source of electromagnetic radiation configured to emit electromagnetic radiation at a predetermined wavelength (λ), for example, between 190 nm and about 400 nm, e.g. 395 nm which in an exemplary implementation, can be used to accelerate and/or modulate and/or facilitate a photopolymerizable insulating and/or dielectric that can be used in conjunction with metal nanoparticles dispersion used in the conductive ink. Other functional heads can be heating elements, additional printing heads with various inks (e.g., support, pre-soldering connective ink, label printing of various components for example capacitors, transistors and the like) and a combination of the foregoing.

Other similar functional steps (and therefore the support systems for affecting these steps) may be taken before or after each of the DI or metallic conducting inkjet ink print heads (e.g., for sintering the conducting layer). These steps may include (but not limited to): a heating step (affected by a heating element, or hot air); photobleaching (of a photoresist mask support pattern), photocuring, or exposure to any other appropriate actininc radiation source (using e.g., a UV light source); drying (e.g., using vacuum region, or heating element); (reactive) plasma deposition (e.g., using pressurized plasma gun and a plasma beam controller); cross linking such as by using cationic initiator e.g. [4-[(2-hydroxytetradecyl)-oxyl]-phenyl]-phenyliodonium hexafluoro antimonate to a flexible resin polymer solutions or flexible conductive resin solutions; prior to coating; annealing, or facilitating redox reactions and their combination regardless of the order in which these processes are utilized. In certain embodiment, a laser (for example, selective laser sintering/melting, direct laser sintering/melting), or electron-beam melting can be used on the rigid resin, and/or the flexible portion. It should be noted, that sintering of the conducting portions can take place even under circumstances whereby the conducting portions are printed on top of a rigid resinous portion of the printed circuit boards including built-in passive and embedded active components described herein component.

Formulating the conducting ink composition may take into account the requirements, if any, imposed by the deposition tool (e.g., in terms of viscosity and surface tension of the composition) and the deposition surface characteristics (e.g., hydrophilic or hydrophobic, and the interfacial energy of the substrate or the support material (e.g., glass) if used), or the substrate layer on which consecutive layers are deposited. For example, the viscosity of either the conducting inkjet ink and/or the DI (measured at the printing temperature ° C.) can be, for example, not lower than about 5 cP, e.g., not lower than about 8 cP, or not lower than about 10 cP, and not higher than about 30 cP, e.g., not higher than about 20 cP, or not higher than about 15 cP. The conducting ink, can each be configured (e.g., formulated) to have a dynamic surface tension (referring to a surface tension when an ink-jet ink droplet is formed at the print-head aperture) of between about 25 mN/m and about 35 mN/m, for example between about 29 mN/m and about 31 mN/m measured by maximum bubble pressure tensiometry at a surface age of 50 ms and at 25° C. The dynamic surface tension can be formulated to provide a contact angle with the peelable substrate, the support material, the resin layer(s), or their combination, of between about 100° and about 165°.

In an exemplary implementation, the term “chuck” is intended to mean a mechanism for supporting, holding, or retaining a substrate or a workpiece. The chuck may include one or more pieces. In one embodiment, the chuck may include a combination of a stage and an insert, a platform, be jacketed or otherwise be configured for heating and/or cooling and have another similar component, or any combination thereof.

In an exemplary implementation, the ink-jet ink compositions, systems and methods allowing for a direct, continuous or semi-continuous ink-jet printing of a printed circuit boards including built-in passive and embedded active components can be patterned by expelling droplets of the liquid ink-jet ink provided herein from an orifice one-at-a-time, as the print-head (or the substrate) is maneuvered, for example in two (X-Y) (it should be understood that the print head can also move in the Z axis) dimensions at a predetermined distance above the removable substrate or any subsequent layer. The height of the print head can be changed with the number of layers, maintaining for example a fixed distance. Each droplet can be configured to take a predetermined trajectory to the substrate on command by, for example a pressure impulse, via a deformable piezo-crystal in an exemplary implementation, from within a well operably coupled to the orifice. The printing of the first inkjet metallic ink can be additive and can accommodate a greater number of layers. The ink-jet print heads provided used in the methods described herein can provide a minimum layer film thickness equal to or less than about 0.3 μm-10,000 μm

The conveyor maneuvering among the various print heads used in the methods described and implementable in the systems described can be configured to move at a velocity of between about 5 mm/sec and about 1000 mm/sec. The velocity of the e.g., chuck can depend, for example, on: the desired throughput, the number of print heads used in the process, the number and thickness of layers of the printed circuit boards including built-in passive and embedded active components described herein printed, the curing time of the ink, the evaporation rate of the ink solvents, the distance between the print head(s) containing the first ink-jet conducting ink of the metal particles or metallic polymer paste and the second print head comprising the second, thermoset resin and board forming inkjet ink, and the like or a combination of factors comprising one or more of the foregoing.

In an exemplary implementation, the volume of each droplet of the metallic (or metallic) ink, and/or the second, resin ink, can range from 0.5 to 300 picoLiter (pL), for example 1-4 pL and depended on the strength of the driving pulse and the properties of the ink. The waveform to expel a single droplet can be a 10V to about 70 V pulse, or about 16V to about 20V, and can be expelled at frequencies between about 2 kHz and about 500 kHz.

The 3D visualization file representing the printed circuit boards including built-in passive and embedded active components used for the fabrication of the printed circuit boards including built-in passive and embedded active components described herein, can be: an an ODB, an ODB++, an .asm, an STL, an IGES, a STEP, a Catia, a SolidWorks, a Autocad, a ProE, a 3D Studio, a Gerber, a Rhino a Altium, an Orcad, an or a file comprising one or more of the foregoing; and wherein file that represents at least one, substantially 2D functional layer (and uploaded to the library) can be, for example, a JPEG, a GIF, a TIFF, a BMP, a PDF file, or a combination comprising one or more raster file of the foregoing.

In certain embodiments, the CAM module further comprises a computer program product for fabricating one or more AME circuit boards including built-in passive and embedded active components, for example, an electronic component, machine part, a connector and the like. The printed component can comprise both discrete metallic (conductive) components and resinous (insulating and/or dielectric) components that are each and both being printed optionally simultaneously or sequentially and continuously, on either a rigid portion or a flexible portion of the PCB and/or FPC. The term “continuous” and its variants are intended to mean printing in a substantially unbroken process. In another embodiment, continuous refers to a layer, member, or structure in which no significant breaks in the layer, member, or structure lie along its length.

The computer controlling the printing process described herein can comprise: a computer readable storage medium having computer readable program code embodied therewith, the computer readable program code when executed by a processor in a digital computing device causes a three-dimensional inkjet printing unit to perform the steps of: pre-process Computer-Aided Design/Computer-Aided Manufacturing (CAD/CAM) generated information (e.g., the 3D visualization file), associated with the AME circuit (in other words, the 3D visualization file representing the AMEs including built-in passive and embedded active components) to be fabricated, thereby creating a library of a plurality of 2D files (in other words, the file that represents at least one, substantially 2D layer for printing the AME circuit layer-by-layer); direct a stream of droplets of a metallic material from a first inkjet print head of the three-dimensional inkjet printing unit at a surface of a substrate; direct a stream of droplets of a DI resin material from a first inkjet print head at the surface of the substrate; alternatively or additionally direct a stream of droplets material from another inkjet print head; move the substrate relative to the inkjet heads in an x-y plane of the substrate, wherein the step of moving the substrate relative to the inkjet heads in the x-y plane of the substrate, for each of a plurality of layers (and/or the patterns of conductive or DI inkjet inks within each layer), is performed in a layer-by-layer fabrication of the AME circuit.

In addition, the computer program, can comprise program code means for carrying out the steps of the methods described herein, as well as a computer program product comprising program code means stored on a medium that can be read by a computer. Memory device(s) as used in the methods described herein can be any of various types of non-volatile memory devices or storage devices (in other words, memory devices that do not lose the information thereon in the absence of power). The term “memory device” is intended to encompass an installation medium, e.g., a CD-ROM, floppy disks, or tape device or a non-volatile memory such as a magnetic media, e.g., a hard drive, optical storage, or ROM, EPROM, FLASH, etc. The memory device may comprise other types of memory as well, or combinations thereof. In addition, the memory medium may be located in a first computer in which the programs are executed (e.g., the 3D inkjet printer provided), and/or may be located in a second different computer which connects to the first computer over a network, such as the Internet. In the latter instance, the second computer may further provide program instructions to the first computer for execution. The term “memory device” can also include two or more memory devices which may reside in different locations, e.g., in different computers that are connected over a network. Accordingly, for example, the bitmap library can reside on a memory device that is remote from the CAM module coupled to the 3D inkjet printer provided, and be accessible by the 3D inkjet printer provided (for example, by a wide area network).

Unless specifically stated otherwise, as apparent from the following discussions, it is appreciated that throughout the specification discussions utilizing terms such as “processing,” “loading,” “in communication,” “detecting,” “calculating,” “determining”, “analyzing,” or the like, refer to the action and/or processes of a computer or computing system, or similar electronic computing device, that manipulate and/or transform data represented as physical, such as a transistor architecture into other data similarly represented as physical structural (in other words, resin or metal/metallic) layers.

Furthermore, as used herein, the term “2D file library” refers to a given set of files that together define a single AME circuit including built-in passive and embedded active components, or a plurality of AME circuits each including built-in passive and embedded active components used for a given purpose. Furthermore, the term “2D file library” can also be used to refer to a set of 2D files or any other raster graphic file format (the representation of images as a collection of pixels, generally in the form of a rectangular grid, e.g., BMP, PNG, TIFF, GIF), capable of being indexed, searched, and reassembled to provide the structural layers of a given PCB, whether the search is for the AME circuit as a whole, or a given specific layer within the AME circuit.

The Computer-Aided Design/Computer-Aided Manufacturing (CAD/CAM) generated information associated with the PCB including built-in passive and embedded active components described herein to be fabricated, which is used in the methods, programs and libraries can be based on converted CAD/CAM data packages can be, for example, IGES, DXF, DWG, DMIS, NC files, GERBER® files, EXCELLON®, STL, EPRT files, an ODB, an ODB++, an .asm, an STL, an IGES, a STEP, a Catia, a SolidWorks, a Autocad, a ProE, a 3D Studio, a Gerber, a Rhino a Altium, an Orcad, an Eagle file or a package comprising one or more of the foregoing. Additionally, attributes attached to the graphics objects transfer the meta-information needed for fabrication and can precisely define the AMEs. Accordingly and in an exemplary implementation, using pre-processing algorithm, GERBER®, EXCELLON®, DWG, DXF, STL, EPRT ASM, and the like as described herein, are converted to 2D files.

A more complete understanding of the components, processes, assemblies, and devices disclosed herein can be obtained by reference to the accompanying drawings. These figures (also referred to herein as “FIG.s”) are merely schematic representations (e.g., illustrations) based on convenience and the ease of demonstrating the present disclosure, and are, therefore, not intended to indicate relative size and dimensions of the devices or components thereof and/or to define or limit the scope of the exemplary embodiments. Although specific terms are used in the following description for the sake of clarity, these terms are intended to refer only to the particular structure of the embodiments selected for illustration in the drawings, and are not intended to define or limit the scope of the disclosure. In the drawings and the following description below, it is to be understood that like numeric designations refer to components of like function.

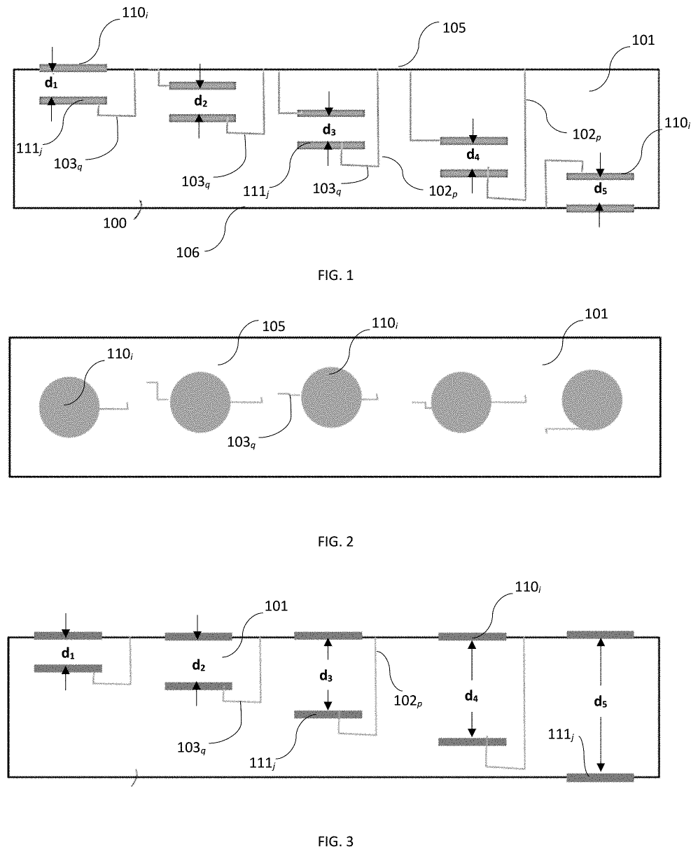

Turning to FIGS. 1-3, illustrating in FIG. 1, a X-Z cross section of AME circuit 100, where horizontal capacitors having upper electrode 110ᵢ and base electrode 111ⱼ are integrally built in, and printed with the systems described, using the methods provided. As illustrated in FIG. 1, several capacitors can be distributed within a single PCB, that as illustrated in FIG. 5B, can form a single modular PCB to be integrated in a larger PCB. Returning to FIG. 1, the electrodes can be embedded at different distances from the top 105, or bottom 106 layer separated by DI 101, yet still have the same distance between the electrodes (e.g., d1=d2=d3=d4=d5) thus providing the AME circuit with varying degree of thermal exposure to chuck temperature, UV and/or IR radiation during curing and/or sintering thus varying control over final performance of electrode plates. As illustrated in FIG. 2, the horizontal capacitors can be formed as discs, thus potentially reducing edge effects prevalent in parallel plate capacitors where the distance between the plates is larger than the plate dimensions as illustrated in FIG. 3 (d3, d4, d5). As illustrated, the parallel plate capacitors can be connected to contact pads (not shown, see e.g., 524, 526 (FIG. 5A) on the top layer of AME circuit 100, with a combination of vias (filled or plated) 102ₚ, and traces 103_{q}. Compared with FIG. 3, where the distance between top electrode 110ᵢ and base electrode 111ⱼ is varied such the exposure of the electrode to IR, and/or UV radiation is maintained at a constant during the building of the additional layers.

Turning to FIGS. 4A-4C illustrating various vertical, parallel plate capacitors. For example, a resistor 131 can be introduced between parallel plate vertical electrode capacitor. Moreover, the methods described, implemented using the systems provided, can be used to fabricate interdigitated capacitors having output line 401 of a first port opening to top layer 105 and output line 402 of a second port opening to bottom layer 106. Using the methods described, the width of output lines 401, and 402 can be predetermined and designed specifically for their intended use in the PCB, either as a discrete component capacitor to be used as a modular component, or integral to a larger PCB. Likewise, other parameters of interdigitated capacitors can be designed and printed directly. These parameters can be, for example at least one of: width and length of terminal strips 405, 406, finger leads 403, 404, finger electrode 421k number and width, which can be the same or different in each port, gaps G₁, G₂, between the terminal strip 405, 406 and their corresponding finger electrodes 421ₖ, spacing s between adjacent parallel finger electrode(s) 421k which can be the same or different for each port (s₁, s₂), and overlap length/of parallel finger electrode(s) 421k.

FIG. 4B, illustrates individual parallel electrode 420ₙ pairs each connected to top layer 105 with (plated or filled) vias 410-414. Here too, the number and length of vias 410-414, as well as electrodes 420n, can be designed and fabricated for their intended purpose. Turning to FIGS. 4C and 4D, illustrating concentric vertical parallel electrode forming a (coaxial) capacitor. As shown, all parameters of cylindrical (or coaxial) capacitor can be designed and fabricated using the systems described with the methods provided. The number of concentric electrodes 422ₗ, the height h of the cylindrical capacitor the radius of each electrode (rₙ) as well as the distance between adjacent cylindrical electrode(s) 422ₗ. Location of output lines 431, 432, 433 likewise can be designed to provide optimal packaging of the cylindrical coaxial capacitor. Furthermore, DI 101 outside the cylindrical capacitor can have the same or different relative permittivity (εᵣ) than DI 101′ inside the cylindrical capacitor. In an exemplary implementation, the DI inside the cylindrical capacitor can be comprised of ceramic comonomers, while the outside DI 101, can be formed of thermoset methacrylates' monomers, oligomers or polymers. DI 101 therefore can be: polyester (PES), polyethylene (PE), polyvinyl alcohol (PVOH), poly(vinylacetate) (PVA), poly-methyl methacrylate (PMMA), Poly (vinyl pirrolidone), or a combination comprising a mixture or a copolymer of one or more of the foregoing.

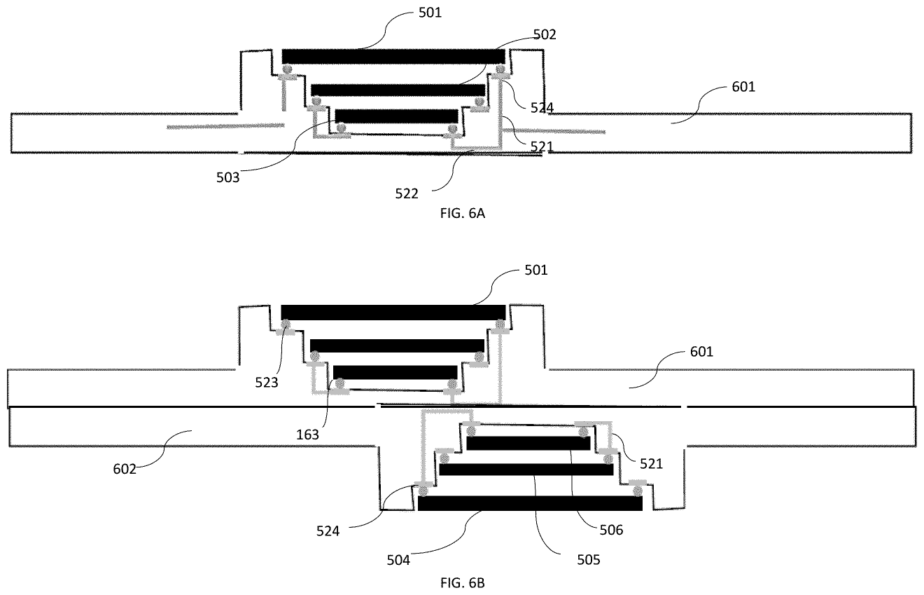

Turning now to FIGS. 5A to 6B, show embodiments of some of the basic structures fabricated using the systems and methods described, and assume that any person skilled in the art of AME circuit design and manufacturing will readily recognize the presence of traces and (filled and/or plated) vias, not necessarily described and/or illustrated in the figures. Accordingly, the figures illustrate various configurations for forming at least one of a plurality of nested concentric contact pads, and an active component receptacle, for vertically-integrated AMEs with each contact pad configured to operably couple to a chip package or otherwise, another active component (e.g., a micro fan), thereby forming a vertically integrated multi-layered PCB. As illustrated in FIG. 5A, the systems provided herein, implementing the methods described, can form step-wise (terraced, ridged) recesses, or wells, or slots or designated sites 161, 162, 163, configured to accommodate and couple active components 501, 502, and 503 respectively. Using the system, and as described herein, it is possible to print using the systems described herein, contact pads 524, 527, either as a terminal end to vias 521 or at the end of traces 522, as illustrated in FIG. 5A. Furthermore, the AMEs printed using the systems described implementing the methods provided, can form a modular AME component to be operably coupled to a larger device, or AME circuit. As illustrated in FIG. 5B, bond pads 510d can be printed, or alternatively, a socket can be integrally printed band used to couple the vertically integrated AME circuit to a larger (or smaller or same size) AME circuit (see e.g., FIG. 6B). Also illustrated in FIGS. 5A-5C, are interconnect balls 523, 526, which can be used as solder balls for active components 501-503. It is noted that the number of vertically integrated active components does not necessarily need to be three as illustrated, and can be at least one. The term “vertically integrated” refers in an exemplary implementation to the integration of at least one of an active component and a passive component, and at least one of an active component and a passive component on the same vertical axis in an X-Z cross section of an XYZ Cartesian coordinate system. As illustrated in FIG. 5C, designated site(s), for example 163, can define an opening 180, configured to provide communication with cooling medium 515, which can be air, or liquid or other gas, or in another embodiment, to other cooling means as described herein. Similarly, via 521 in FIG. 5C is, in an exemplary implementation, a plated via operating as a heat pipe or heat wick. FIG. 5D, illustrates an exemplary implementation of an AME circuit module, which, in addition to embedded active components 501-503, further comprise battery receptacle (or open housing) 540, configured to accommodate and engage battery 700 (not shown), and includes battery electrodes 541, and 542, configured to, for example, power inductor (or antenna) 550, that in certain embodiment, can be used to power lower voltage active components. Turning to FIG. 5E, showing an isometric view of a similar arrangement illustrated in FIG. 5D whereby the vertically integrated ICs 501-503 are powered by an integrally printed induction coil 551, powered through a battery placed in a specifically fabricated well 540, including the necessary contacts 541, 542 for the battery. This structure can be used in an exemplary implementation in application where wireless communication is required or inductive devices are required.

In an exemplary implementation, the vertically integrated AME circuit 601 illustrated in FIG. 6A, can be coupled to vertically integrated AME circuit 602 (see e.g., FIG. 6B), thus forming a double-sided, vertically integrated AME circuit. As described previously, a socket can be printed into one or both AME circuits, configured to enable electric and mechanical coupling the double-sided, vertically integrated AME circuit to other AMEs. It is contemplated, that the vertically integrated AME circuits illustrated herein can be used as boards in current processes that do not necessarily use additive manufacturing as units blocks to which ICs and other components can be coupled, and additionally or alternatively, the shown AMEs can be added to larger (or smaller) AMEs not fabricated using additive manufacturing.

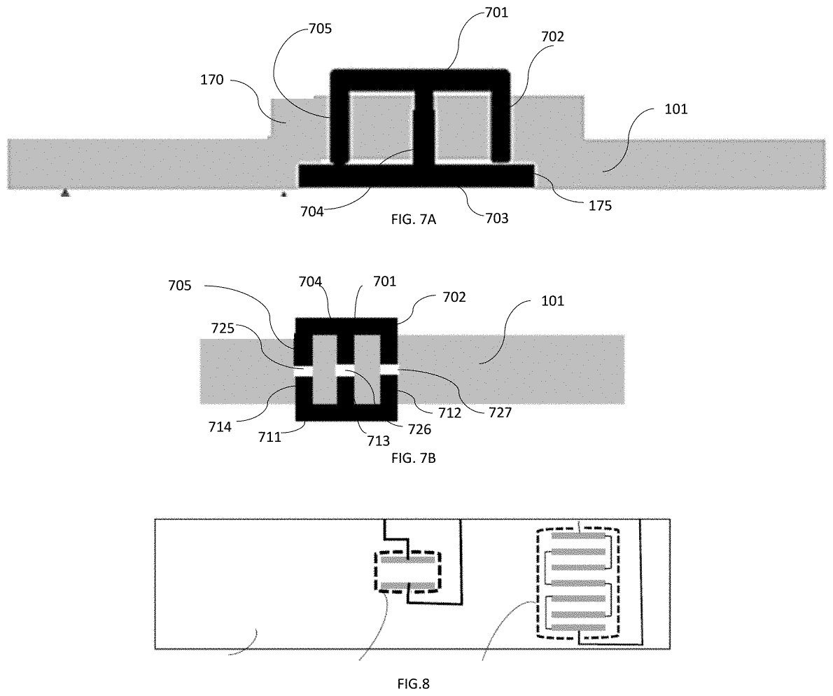

Turning now to FIGS. 7A, 7B, illustrating a passive grounded monodirectional DC-DC converter, and a bidirectional DC-DC converter in FIG. 7B. As illustrated in FIG. 7A, it is possible to form first current loops 701, 702, 703, 704, and a second current loop 701, 704, 703, 705 with bar 704 forming a ground. In addition, and as illustrated in FIG. 7B, current loops can be interrupted by integrally printed capacitors 725, 726, 727, in formed current loops 701, 705, 714, 711, 713, 704, and 701, 702, 712, 711, 713, 704.

FIG. 8 illustrates a configuration using additive manufacturing to provide radiation, UV, electromagnetic, and RF shielding for embedded capacitors, inductors, resistors (transistors or other chip packages in need of such protection). For example, FIG. 8 illustrates simple dual plate 811, 811′ horizontal capacitor (left), as well as interdigitated capacitor plates' 821h (see e.g., FIG. 4A) arrangement (right), both encased in a UV/RF/Radiation shielding capsule 810, 820, fabricated using additive manufacturing. The capsule can be either floating (in other words, ungrounded), or grounded, with openings 816, 819, and 827, 830 at the top and bottom, which can enable contact 815, and 829 and 817 of with either a blind via or buried via to couple to capacitor plates 811, 811′ and 821h. Similar arrangement can be made for the serial connectivity of the plates as well as with vertical plates (see e.g., FIG. 4A). Shielding capsules 810, 811, can be made entirely of metallic material or, in certain embodiment wholly or partially, from ceramic material. Other passive components can be shielded, for example in circumstances where “cross talk” or parasitic relations between adjacent chip packages or other passive components needs to be curbed.

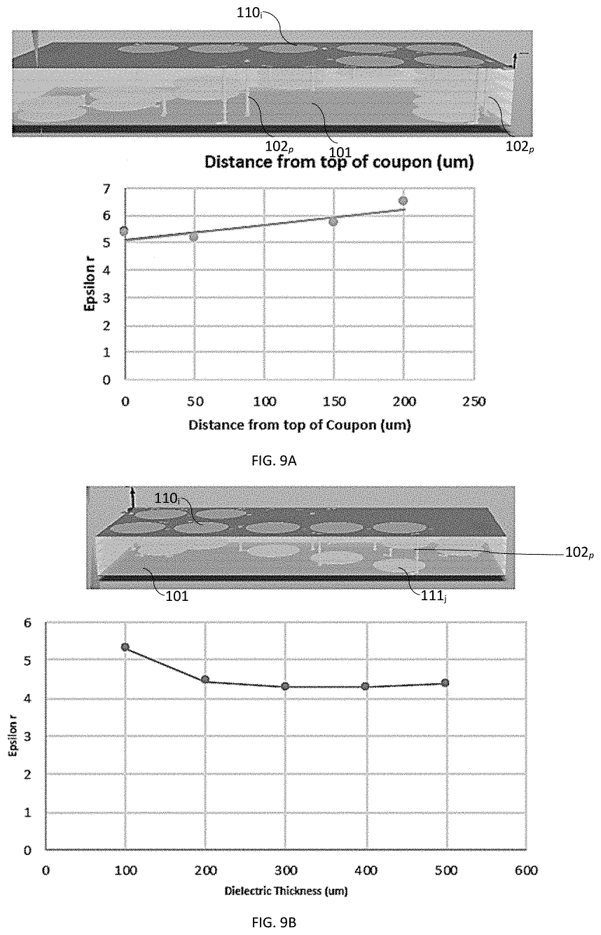

Turning now to FIGS. 9A, 9B, illustrating a graph (bottom) showing the dependence of relative permittivity (εᵣ) on horizontal capacitors' having fixed dielectric (DI) thickness between electrodes as a function of the distance of the top electrode 110; from the top surface 105 of the PCB (i.e. DI thickness) in a Z-X cross section of an AME circuit (coupon), as described for example, in FIG. 1, with FIG. 9B showing a graph (bottom) of the dependence of relative permittivity (εᵣ) on horizontal capacitors' having varying dielectric (DI) thickness as described and illustrated in FIG. 3, between electrodes as a function of the thickness between electrodes in a Z-X cross section of an AME circuit (coupon) schematic. As shown, for fixed distance between parallel electrodes 110ᵢ and 111ⱼ, the relative permittivity (εr) is proportional to the distance of the top electrode 110ᵢ from the top surface of the coupon. Conversely, beyond a threshold distance between parallel electrodes 110ᵢ and 111ⱼ, at about 250 μm, the relative permittivity (εᵣ) plateaus and remains constant. In an exemplary implementation, this arrangement can be used to provide improved thermomechanical stability and performance consistency and reliability to passive capacitor components, during fabrication process.

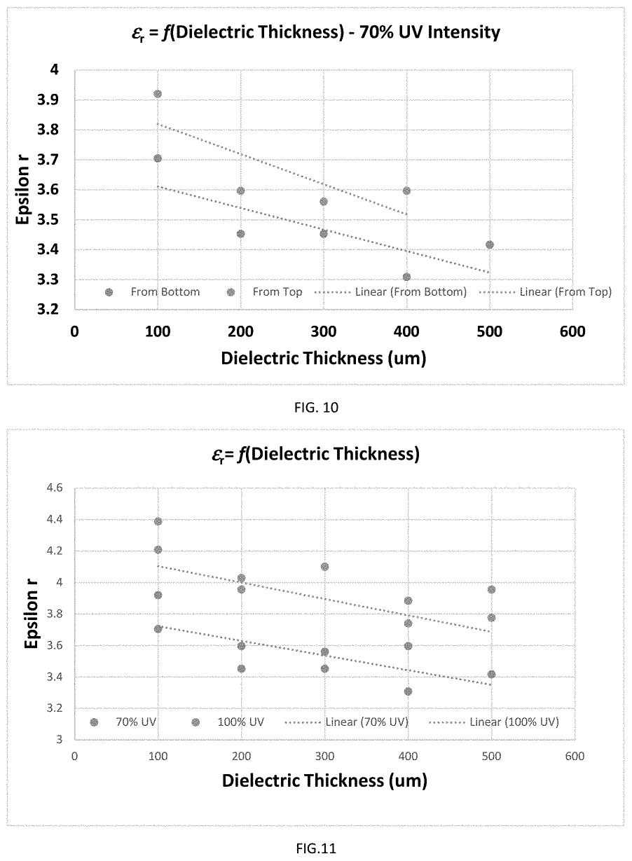

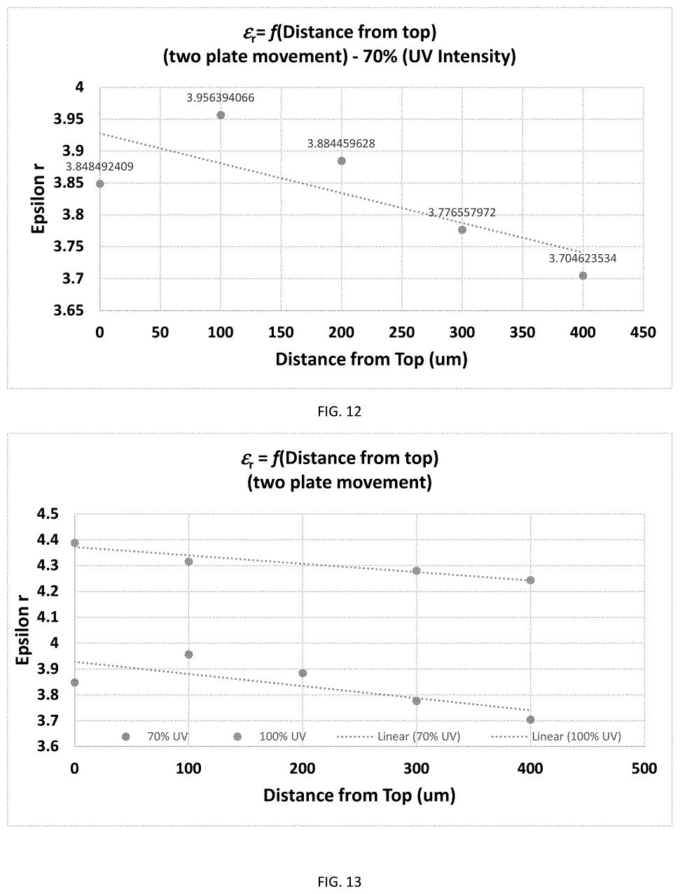

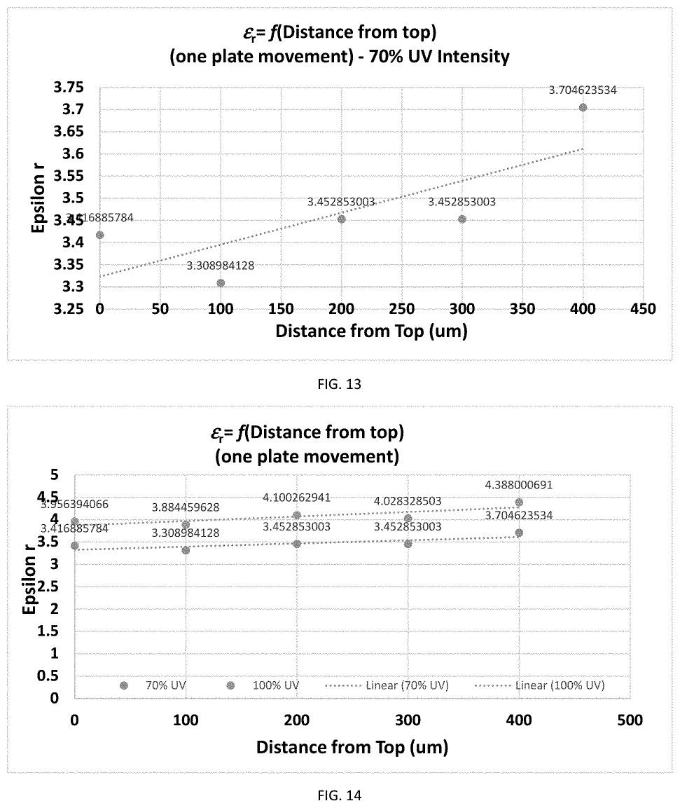

Likewise, FIGS. 10-15 are graphs showing the dependence of relative permittivity (εᵣ) on various processing variables in entirely embedded capacitors fabricated using the methods provided herein. These include permittivity (εᵣ) as a function of dielectric thickness when DI was cured using UV at 70% of full strength (FIG. 10); as a function of dielectric thickness when DI was cured using UV at both 70% (bottom), and 100% (tom) of full strength (FIG. 11); as a function of dielectric thickness from top layer when DI was cured using UV at 70% of full strength with two plates' capacitor movement (e.g., FIG. 1) (FIG. 12); as a function of dielectric thickness from top layer when DI was cured using UV at 70% (bottom), and 100% (top) of full strength with two plates' capacitor movement (see e.g., FIG. 1) (FIG. 13); as a function of dielectric thickness from top layer when DI was cured using UV at 70% of full strength with one plates' capacitor movement (e.g., FIG. 3) (FIG. 14); and as a function of dielectric thickness from top layer when DI was cured using UV at 70% (bottom), and 100% (top) of full strength with one plates' capacitor movement (see e.g., FIG. 3) (FIG. 13). It is noted that the permittivity of free space used in the calculations provided herein, —a vacuum—is equal to about 8.85×10⁻¹² Farads/meter (F/m). As used herein, relative permittivity (εᵣ): is permittivity of a given material relative to that of the permittivity of a vacuum.

The term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives.

All ranges disclosed herein are inclusive of the endpoints, and the endpoints are independently combinable with each other. “Combination” is inclusive of blends, mixtures, alloys, reaction products, and the like. The terms “a”, “an” and “the” herein do not denote a limitation of quantity, and are to be construed to cover both the singular and the plural, unless otherwise indicated herein or clearly contradicted by context. The suffix “(s)” as used herein is intended to include both the singular and the plural of the term that it modifies, thereby including one or more of that term (e.g., the print head(s) includes one or more print head). Reference throughout the specification to “one embodiment”, “another embodiment”, “an exemplary implementation”, and so forth, when present, means that a particular element (e.g., feature, structure, and/or characteristic) described in connection with the embodiment is included in at least one embodiment described herein, and may or may not be present in other embodiments. In addition, it is to be understood that the described elements may be combined in any suitable manner in the various embodiments. Furthermore, the terms “first,” “second,” and the like, herein do not denote any order, quantity, or importance, but rather are used to denote one element from another.

Likewise, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such.

Accordingly, in an exemplary implementation, provided herein is an additive manufacturing electronic (AME) circuit, comprising a plurality of at least one of a capacitor, an inductor and a resistor, each embedded entirely within a dielectric matrix, wherein (i) each of at least one of the capacitor, inductor and resistor comprises at least one pair of horizontal or vertical plates (ii) the pair of the horizontal plates are coupled by at least one of a blind via, buried via, and a through hole via, wherein (iii) at least one capacitor is an interdigitated capacitor, (iv) the vertical capacitor is a multi-plate capacitor, wherein (v) at least on capacitor is encapsulated in at least one of: a floating, and grounded shielding metallic capsule, each adapted to shield the at least one capacitor from at least one of: a UV, electromagnetic, and radio frequency irradiation, and wherein (vi) the shielding capsule comprises ceramics.

In another exemplary implementation, provided herein is an AME circuit comprising a plurality of concentric nested contact pads, and an active component receptacle, each contact pad sized and configured to operably couple to at least one of: a chip, and a chip package, wherein (vii) the chip package is at least one of: a Quad Flat Pack (QFP) package, a Thin Small Outline Package (TSOP), a Small Outline Integrated Circuit (SOIC) package, a Small Outline J-Lead (SOJ) package, a Plastic Leaded Chip Carrier (PLCC) package, a Wafer Level Chip Scale Package (WLCSP), a Mold Array Process-Ball Grid Array (MAPBGA) package, a Quad Flat No-Lead (QFN) package, and a Land Grid Array (LGA) package, while further comprising (viii) an induction coil surrounding the concentric nested contact pads, and/or (ix) an induction coil not surrounding the concentric nested contact pads, in other words, entirely embedded in the DI matrix in a location that does not include any contact pad, wherein (x) the induction coil surrounding the nested contact pad is in electric communication with a battery well, (the AME circuit) further comprising (xi) at least one of: a resistor, a capacitor, a coil, an antenna, a cooling pad, a heat-pipe, a condenser, a wick, a cooling platform, a vapor chamber, and a socket, (xii) further comprising a hollow intermediate layer and wherein at least one of: the cooling pad, the heat pipe, and the wick, each terminates at the hollow intermediate layer, wherein (xiii) the AME circuit having an upper side comprising the plurality of concentric nested contact pads, and the active component receptacle, and a bottom side comprising a plurality of bond pads, and wherein (xiv) the AME circuit having an upper side comprising the plurality of concentric nested contact pads, and the active component receptacle, and a bottom side comprising a plurality of bond pads is coupled to another AME circuit having an upper side comprising the plurality of concentric nested contact pads, and the active component receptacle, and a bottom side comprising a plurality of bond pads by the plurality of bond pads,

In yet another exemplary implementation, provided herein is a method for reducing the form factor of an additive manufacturing electronic (AME) circuit comprising a plurality of passive and active components using additive manufacturing comprising: providing an ink jet printing system having: a first print head adapted to dispense a dielectric ink; a second print head adapted to dispense a conductive ink; a conveyor, operably coupled to the first and second print heads, configured to convey a substrate to each print heads; and a computer aided manufacturing (“CAM”) module in communication with the first print head, the second print heads, and the conveyor, the CAM module comprising: at least one processor; a non-volatile memory; and a set of executable instructions stored on the non-volatile memory, configured, when executed to cause the at least one processor to: receive a 3D visualization file representing the infrastructure element; using the 3D visualization file, generate a library comprising a plurality of layer files, each layer file representing a substantially 2D layer for printing of the AME circuit comprising the plurality of embedded passive and active components; using the library, generate a conductive ink pattern comprising the conductive portion of each of the layer files for printing a conductive portion of the AME circuit using the library, generate an ink pattern corresponding to the dielectric inkjet ink portion of each of the layer files for printing a dielectric portion of the AME circuit, wherein the CAM module is configured to control each of the first and the second print heads; providing the dielectric inkjet ink composition, and the conductive inkjet ink composition; using the CAM module, obtaining the file corresponding to the first layer; using the first print head, forming the pattern corresponding to the dielectric inkjet ink; curing the pattern corresponding to the at least one of the insulating and the dielectric inkjet ink; using the second print head, forming the pattern corresponding to the conductive inkjet ink; sintering the pattern corresponding to the conductive inkjet ink; and optionally coupling at least one active component to the printed first layer, wherein the conductive inkjet ink and the dielectric inkjet ink are adapted to form passive components embedded within the first layer, wherein (xv) the set of executable instructions are further configured, when executed to cause the at least one processor to: using the 3D visualization file, generate a library of a plurality of subsequent layers' files each subsequent file represents a substantially two dimensional (2D) subsequent layer for printing a subsequent portion of the AME circuit comprising the plurality of embedded passive and active components, wherein each subsequent layer file is indexed by printing order, (xvi) further comprising, following the step of sintering the pattern corresponding to the conductive inkjet ink: using the CAM module, accessing the library; obtaining a generated file representing 2D subsequent layer of the AME circuit; and repeating the steps for forming the subsequent layer, wherein (xvii) the passive component is at least one of: an inductor, a capacitor, a resistor, a coil, an antenna, a cooling pad, a heat-pipe, a condenser, a wick, a cooling platform, a vapor chamber, a socket, and a contact pad, (xviii) the AME circuit is a multi-layered AME circuit defining a hollow intermediate layer and wherein at least one of a cooling pad, a heat pipe, and a wick, each terminates at the hollow intermediate layer, wherein (xix) the capacitor is at least one of: a concentric capacitor, a horizontal capacitor, a vertical capacitor, and an interdigitated capacitor, the method further comprising, (xx) forming at least one of a plurality of nested concentric contact pads, and an active component receptacle, each contact pad configured to operably couple to at least one of: a chip, and a chip package, thereby forming a vertically integrated multi-layered AME circuit, wherein (xxi) the hollow intermediate layer is in fluid communication with at least one of: a cooling liquid source, a cooling gas source, and a cooling air source, wherein (xxii) the chip package is at least one of: a Quad Flat Pack (QFP) package, a Thin Small Outline Package (TSOP), a Small Outline Integrated Circuit (SOIC) package, a Small Outline J-Lead (SOJ) package, a Plastic Leaded Chip Carrier (PLCC) package, a Wafer Level Chip Scale Package (WLCSP), a Mold Array Process-Ball Grid Array (MAPBGA) package, a Quad Flat No-Lead (QFN) package, and a Land Grid Array (LGA) package, wherein (xxiii) the additive manufacturing systems further comprises a robotic arm, the method further comprising: depositing solder paste on at least one of the plurality of contact pads; and using the robotic arm, placing the chip package on at least one of the plurality of contact pads, wherein (xxiv) the pattern representative of the conductive inkjet ink is configured to fabricate interconnect balls, (xxv) the additive manufacturing systems further comprises a third print head adapted to dispense a second conductive inkjet ink, the method further comprising: providing the second conductive ink composition; using the second conductive ink print head, forming a predetermined pattern corresponding to the second conductive inkjet ink, the pattern being a 2D presentation of a connecting terminal, a bond to a lead, an interconnect ball, or a combination comprising the foregoing, (xxvi) the conductive inkjet ink in the first print head comprises silver and the second conductive inkjet ink comprises copper, and wherein (xxvii) the active component receptacle is a battery receptacle.

Although the foregoing disclosure for 3D printing of printed circuit boards including built-in passive and embedded active components using inkjet printing based on converted 3D visualization CAD/CAM data packages has been described in terms of some embodiments, other embodiments will be apparent to those of ordinary skill in the art from the disclosure herein. Moreover, the described embodiments have been presented by way of example only, and are not intended to limit the scope of the inventions. Indeed, the novel methods, programs, libraries and systems described herein may be embodied in a variety of other forms without departing from the spirit thereof. Accordingly, other combinations, omissions, substitutions and modifications will be apparent to the skilled artisan in view of the disclosure herein.

1. An additive manufacturing electronic (AME) circuit, comprising a plurality of at least one of a capacitor, an inductor and a resistor, each embedded entirely within a dielectric matrix.

2. The AME circuit of claim 1, wherein each of at least one of: the capacitor, inductor and resistor comprises at least one pair of horizontal or vertical plates.

3. The AME circuit of claim 2, wherein the pair of the horizontal plates are coupled by at least one of a blind via, buried via, and a through hole via.

4. The AME circuit of claim 3, wherein at least one capacitor is an interdigitated capacitor.

5. The AME circuit of claim 2, wherein the vertical capacitor is a multi-plate capacitor.

6. The AME circuit of claim 1, wherein at least on capacitor is encapsulated in at least one of: a floating, and grounded shielding metallic capsule, each adapted to shield the at least one capacitor from at least one of: a UV, electromagnetic, and radio frequency irradiation.

7. The AME circuit of claim 6, wherein the shielding capsule comprises ceramics.

8. An AME circuit comprising a plurality of concentric nested contact pads, and an active component receptacle, each contact pad sized and configured to operably couple to at least one of: a chip, and a chip package.

9. The AME circuit of claim 8, wherein the chip package is at least one of: a Quad Flat Pack (QFP) package, a Thin Small Outline Package (TSOP), a Small Outline Integrated Circuit (SOIC) package, a Small Outline J-Lead (SOJ) package, a Plastic Leaded Chip Carrier (PLCC) package, a Wafer Level Chip Scale Package (WLCSP), a Mold Array Process-Ball Grid Array (MAPBGA) package, a Quad Flat No-Lead (QFN) package, and a Land Grid Array (LGA) package.

10. The AME circuit of claim 9, further comprising an induction coil surrounding the concentric nested contact pads.

11. The AME circuit of claim 9, further comprising an induction coil not surrounding the concentric nested contact pads.

12. The AME circuit of claim 10, wherein the induction coil is in electric communication with a battery well.

13. The AME circuit of claim 11, further comprising at least one of: a resistor, a capacitor, a coil, an antenna, a cooling pad, a heat-pipe, a condenser, a wick, a cooling platform, a vapor chamber, and a socket.

14. The AME circuit of claim 13, further comprising a hollow intermediate layer and wherein at least one of: the cooling pad, the heat pipe, and the wick, each terminates at the hollow intermediate layer.

15. The AME circuit of claim 8, having an upper side comprising the plurality of concentric nested contact pads, and the active component receptacle, and a bottom side comprising a plurality of bond pads.

16. The AME circuits of claim 15, coupled to another AME circuit of claim 15 by the plurality of bond pads.

17. A method for reducing the form factor of an additive manufacturing electronic (AME) circuit comprising a plurality of passive and active components using additive manufacturing comprising:
a. providing an ink jet printing system having:
i. a first print head adapted to dispense a dielectric ink;
ii. a second print head adapted to dispense a conductive ink;
iii. a conveyor, operably coupled to the first and second print heads, configured to convey a substrate to each print heads; and
iv. a computer aided manufacturing (“CAM”) module in communication with the first print head, the second print heads, and the conveyor, the CAM module comprising: at least one processor; a non-volatile memory; and a set of executable instructions stored on the non-volatile memory, configured, when executed to cause the at least one processor to:
1. receive a 3D visualization file representing the infrastructure element;
2. using the 3D visualization file, generate a library comprising a plurality of layer files, each layer file representing a substantially 2D layer for printing of the AME circuit comprising the plurality of embedded passive and active components;
3. using the library, generate a conductive ink pattern comprising the conductive portion of each of the layer files for printing a conductive portion of the AME circuit
4. using the library, generate an ink pattern corresponding to the dielectric inkjet ink portion of each of the layer files for printing a dielectric portion of the AME circuit, wherein the CAM module is configured to control each of the first and the second print heads;
b. providing the dielectric inkjet ink composition, and the conductive inkjet ink composition;
c. using the CAM module, obtaining the file corresponding to the first layer;
d. using the first print head, forming the pattern corresponding to the dielectric inkjet ink;
e. curing the pattern corresponding to the at least one of the insulating and the dielectric inkjet ink;
f. using the second print head, forming the pattern corresponding to the conductive inkjet ink;
g. sintering the pattern corresponding to the conductive inkjet ink; and
h. optionally coupling at least one active component to the printed first layer, wherein the conductive inkjet ink and the dielectric inkjet ink are adapted to form passive components embedded within the first layer.

18. The method of claim 17, wherein the set of executable instructions are further configured, when executed to cause the at least one processor to: using the 3D visualization file, generate a library of a plurality of subsequent layers' files each subsequent file represents a substantially two dimensional (2D) subsequent layer for printing a subsequent portion of the AME circuit comprising the plurality of embedded passive and active components, wherein each subsequent layer file is indexed by printing order.

19. The method of claim 18, further comprising, following the step of sintering the pattern corresponding to the conductive inkjet ink:
a. using the CAM module, accessing the library;
b. obtaining a generated file representing 2D subsequent layer of the AME circuit; and
c. repeating the steps for forming the subsequent layer.

20. The method of claim 19, wherein the passive component is at least one of: an inductor, a capacitor, a resistor, a coil, an antenna, a cooling pad, a heat-pipe, a condenser, a wick, a cooling platform, a vapor chamber, a socket, and a contact pad.

21. The method of claim 20, wherein the AME circuit is a multi-layered AME circuit defining a hollow intermediate layer and wherein at least one of a cooling pad, a heat pipe, and a wick, each terminates at the hollow intermediate layer.

22. The method of claim 20, wherein the capacitor is at least one of: a concentric capacitor, a horizontal capacitor, a vertical capacitor, and an interdigitated capacitor.

23. The method of claim 21, further comprising, forming at least one of a plurality of nested concentric contact pads, and an active component receptacle, each contact pad configured to operably couple to at least one of: a chip, and a chip package, thereby forming a vertically integrated multi-layered AME circuit.

24. The method of claim 21, wherein the hollow intermediate layer is in fluid communication with at least one of: a cooling liquid source, a cooling gas source, and a cooling air source.

25. The method of claim 23, wherein the chip package is at least one of: a Quad Flat Pack (QFP) package, a Thin Small Outline Package (TSOP), a Small Outline Integrated Circuit (SOIC) package, a Small Outline J-Lead (SOJ) package, a Plastic Leaded Chip Carrier (PLCC) package, a Wafer Level Chip Scale Package (WLCSP), a Mold Array Process-Ball Grid Array (MAPBGA) package, a Quad Flat No-Lead (QFN) package, and a Land Grid Array (LGA) package.

26. The method of claim 25, wherein the additive manufacturing systems further comprises a robotic arm, the method further comprising:
a. depositing solder paste on at least one of the plurality of contact pads; and
b. using the robotic arm, placing the chip package on at least one of the plurality of contact pads.

27. The method of claim 23, wherein the pattern representative of the conductive inkjet ink is configured to fabricate interconnect balls.

28. The method of claim 17, wherein the additive manufacturing systems further comprises a third print head adapted to dispense a second conductive inkjet ink, the method further comprising:
a. providing the second conductive ink composition;
b. using the second conductive ink print head, forming a predetermined pattern corresponding to the second conductive inkjet ink, the pattern being a 2D presentation of a connecting terminal, a bond to a lead, an interconnect ball, or a combination comprising the foregoing.

29. The method of claim 28, wherein the conductive inkjet ink in the first print head comprises silver and the second conductive inkjet ink comprises copper.

30. The method of claim 23, wherein the active component receptacle is a battery receptacle.

31. An AME circuit comprising a plurality of passive and active components and having a reduced form factor fabricated by any one of claims 17-30.
